(19) United States
(12) Patent Application Publication
(10) Pub. No.: US 2017/0256381 A1
(43) Pub. Date: Sep. 7, 2017

(54) SUBSTRATE PROCESSING APPARATUS

(71) Applicant: TOKYO ELECTRON LIMITED, Tokyo (JP)

(72) Inventor: Kazuki DENPOH, Tokyo (JP)

(21) Appl. No.: 15/441,324

(22) Filed: Feb. 24, 2017

(30) Foreign Application Priority Data
Mar. 2, 2016 (JP) 2016-040060

(51) Int. Cl. H01J 37/32; C23C 16/505; C23C 16/52; C23C 16/455

(52) U.S. Cl. CPC H01J 37/32128; H01J 37/3244; H01J 37/32724; C23C 16/45544; C23C 16/45536; C23C 16/505; C23C 16/52; H01J 2237/332

(57) ABSTRACT

There is provided a substrate processing apparatus which performs a film forming process by supplying a raw material gas to a substrate and irradiating plasma onto the substrate, the apparatus including: a processing container configured to hermetically accommodate a mounting table on which the substrate is mounted; and a plasma source configured to generate plasma in the processing container. The plasma source includes a high-frequency power source that generates plasma and a sheath potential reducing means configured to reduce a sheath potential of the generated plasma.

### CROSS-REFERENCE TO RELATED APPLICATION

This application claims the benefit of Japanese Patent Application No. 2016-040060, filed on Mar. 2, 2016, in the Japan Patent Office, the disclosure of which is incorporated herein in its entirety by reference.

### TECHNICAL FIELD

The present disclosure relates to a substrate processing apparatus that performs a film forming process with respect to a surface of a substrate.

### BACKGROUND

For example, in the manufacturing process of a semiconductor device or the like, various kinds of processes such as an ion implantation process, an etching process, a film forming process or the like, are carried out with respect to a semiconductor wafer (hereinafter, also simply referred to as a “wafer”) as a substrate. As a method of forming a film on a wafer, a so-called ALD (Atomic Layer Deposition) process (hereinafter, also simply referred to as an ALD process) is sometimes used. In the ALD process, for example, a raw material gas is supplied into a processing container kept in vacuum through exhaustion and then adsorbed onto a surface of a wafer. Thereafter, a portion of the raw material gas is fixed onto the surface of the wafer through a reduction reaction or the like so that a film is formed on the wafer. As such, even in a wafer having, for example, a pattern of a concave-convex shape, the film may be formed to have a uniform thickness over the entire surface of the wafer.

However, the film forming process using the ALD process requires a heating process of thermally treating the wafer at, for example, a high temperature of approximately 600 degrees C. This increases a thermal budget (thermal history) of the wafer. However, since a shallow junction is prompted along with the miniaturization of the semiconductor, such a thermal budget is required to be small. To meet the requirement, in recent years, there is employed a so-called plasma enhanced ALD (hereinafter, also referred to as PEALD) which irradiates plasma onto a wafer in which a raw material gas is adsorbed onto the surface thereof so as to fix the raw material gas onto the surface of the wafer, thus forming a film on the wafer, instead of the heating process.

For example, the conventional CVD process is carried out in an Ar-rich atmosphere, whereas the PEALD process is carried out in an H₂-rich atmosphere because a lot of H₂ is supplied into a processing container in which the PEALD process is performed. In the PEALD-based apparatus, a film formation control for each atomic layer is executed by alternately repeating the adsorption of the raw material gas onto the surface of the wafer and the plasma irradiation. In this way, a film thickness is precisely controlled. At this time, H₃⁺ ions are incident onto a surface of a film deposited on the wafer. The lighter the incident ions are, the deeper the ions are implanted into the deposited film at the same energy. That is to say, since the H₃⁺ ion is lighter than the Ar⁺ ion, when comparing these ions with each other at the same energy, the H₃⁺ ions may be implanted deeper than the Ar⁺ ions implanted in the conventional CVD process.

If the H₃⁺ ions are implanted deeply into a formed film, a damaged surface texture caused by the impact of the respective ions is manifested in the deposited film. In this regard, for example, in a plasma processing apparatus, there is disclosed a technology which reduces an ion energy by increasing a frequency of a driving voltage to be applied to an electrode and also performs an etching process at a high selectivity. In other words, a technology for reducing an ion energy by applying a high-frequency voltage is well known. From this, it is estimated that the damage to the film described above can be suppressed by reducing the ion energy.

In recent years, as a shallow junction is prompted with the miniaturization of a semiconductor, a thin film formation process including a micro-processing is required. Thus, the PEALD process is adopted rather than the CVD process. This is due to the fact that, in the case where a film forming process for a device of a shape having a further high aspect ratio or overhang is required, the conventional CVD method using the impact of the Ar⁺ ions has a limit to apply a plasma process (for example, desorbing Cl when forming a Ti film) with respect to portions such as the side wall of a hole or the shadow of the overhang, whereas the PEALD process is effective for a thermo-chemical reaction by H radicals.

However, the adoption of the PEALD process causes a problem in which the H₃⁺ ions are implanted deeply into a film formed during the plasma process, which result in damage to the deposited film. As described above, although it is presumed that the PEALD process suppresses the damage to the deposited film by reducing the ion energy, technologies or detailed conditions for properly suppressing the damage by efficiently reducing the ion energy have not yet been devised.

### SUMMARY

Some embodiments of the present disclosure provide a substrate processing apparatus using a PEALD process, which can significantly reduce energy of ions to be incident onto a wafer and suppress damage to a deposited film, caused by implantation of the ions, thus implementing a film forming process with good surface texture.

According to one embodiment of the present disclosure, there is provided a substrate processing apparatus which performs a film forming process by supplying a raw material gas to a substrate and irradiating plasma onto the substrate, the apparatus including: a processing container configured to hermetically accommodate a mounting table on which the substrate is mounted; and a plasma source configured to generate plasma in the processing container. The plasma source includes a high-frequency power source that generates plasma, and a sheath potential reducing means configured to reduce a sheath potential of the generated plasma.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical cross-sectional view schematically illustrating a configuration of a plasma processing apparatus according to the present embodiment.

FIGS. 2A and 2B are schematic explanatory views of a film forming process of forming a Ti film on a wafer W.

FIGS. 3A and 3B are schematic explanatory views related to damage.

FIG. 4 is a graph showing a change in electron density and a change in generation rate of H radicals, as a function of a change in frequency of a power source.

FIG. 5 is a graph showing a change in energy of H₃⁺ ions, as a function of a change in frequency of a high-frequency power source and a change in Vₚₚ at 27 MHz.

FIG. 6 is a fundamental waveform corresponding to one cycle of a sine wave in a high-frequency power source with an application voltage Vₚₚ of 700V and a frequency of 27 MHz, according to the related art.

FIG. 7 is a high-frequency waveform in a high-frequency power source with an application voltage Vₚₚ of 400V and a frequency of 27 MHz, according to the present embodiment.

FIGS. 8A to 8C are graphs schematically showing waveforms in the case of changing the slope of a portion L1 corresponding to one wavelength having positive-negative potentials in a high-frequency waveform according to the present embodiment.

FIG. 9 is a graph showing a change in electron density (plasma density) and a change in generation efficiency (generation rate) of H radicals when changing the slope (dV/dt) in a high-frequency waveform according to the present embodiment.

FIGS. 10A and 10B are graphs for explaining dependency on sign of a high-frequency waveform according to the present embodiment.

FIGS. 11A and 11B are explanatory graphs illustrating electron density distributions corresponding to respective high-frequency waveforms shown in FIGS. 10A and 10B.

FIGS. 12A and 12B are graphs showing a change in ion energy in the case of performing a high-frequency oscillation using a high-frequency power source with respective high-frequency waveforms shown in FIGS. 10A and 10B when forming a Ti film, in a plasma processing apparatus according to the present embodiment.

### DETAILED DESCRIPTION

Hereinafter, an example of the embodiments of the present disclosure will be described with reference to the accompanying drawings. In the present specification and drawings, components having substantially identical functions and configurations will be designated by like reference numerals with duplicate descriptions thereof omitted. In addition, the present embodiment will be described by taking, as an example, a case in which a substrate processing apparatus is a plasma processing apparatus 1 that processes a substrate using plasma and a Ti film is formed on a wafer W by the plasma processing apparatus 1.

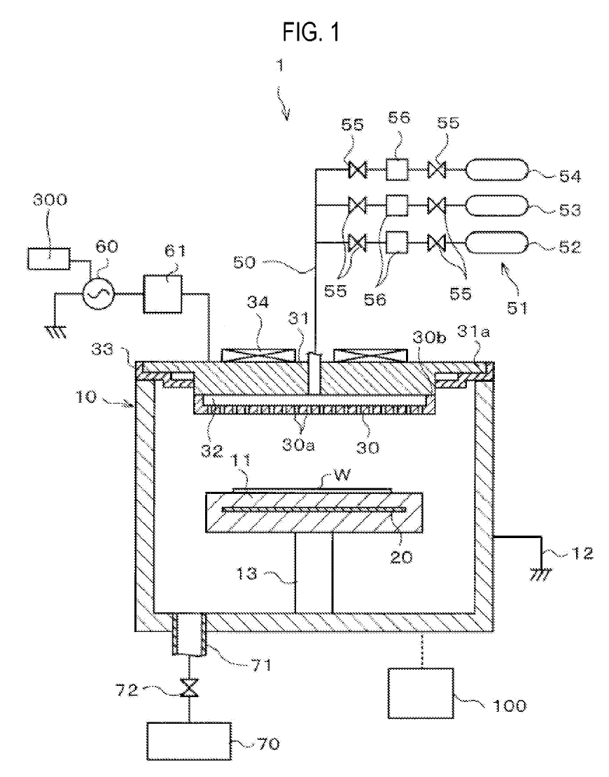

FIG. 1 is a vertical cross-sectional view schematically illustrating a configuration of the plasma processing apparatus 1 as a substrate processing apparatus according to the present embodiment. The plasma processing apparatus 1 includes a processing container 10 having a substantially cylindrical shape with a bottom and an opened upper portion, and a mounting table 11 installed in the processing container 10 to mount a wafer W thereon. The processing container 10 is electrically grounded to the earth by a ground wire 12. In addition, an inner wall of the processing container 10 is covered with, for example, a liner (not shown) having a thermal sprayed film formed on the surface thereof. The thermal sprayed film is made of a plasma-resistant material.

The mounting table 11 is formed of, for example, ceramics such as aluminum nitride (AlN). A surface of the mounting table 11 is coated with a film (not shown) made of a conductive material. A lower surface of the mounting table 11 is supported by a support member 13 formed of a conductive material, while being electrically connected to the support member 13. A lower end of the support member 13 is supported by a bottom surface of the processing container 10 while being electrically connected to the bottom surface. Accordingly, the mounting table 11 is grounded through the processing container 10 so that the mounting table 11 functions as a lower electrode that is paired with an upper electrode 30 to be described later. In addition, the configuration of the lower electrode is not limited to contents of the present embodiment. As an example, the lower electrode may be configured by embedding a conductive member such as a metal mesh in the mounting table 11.

The mounting table 11 includes an electric heater 20 incorporated therein, thus heating the wafer W mounted on the mounting table 11 to a predetermined temperature. In addition, the mounting table 11 includes a clamp ring (not shown) which presses a peripheral portion of the wafer W to fix the wafer W onto the mounting table 11, and elevating pins (not shown) which transfers the wafer W between a transfer mechanism (not shown) installed outside the processing container 10 and the mounting table 11.

The upper electrode 30 formed in a substantially disc shape is installed above the mounting table 11 used as the lower electrode and in an inner side of the processing container 10 to face the mounting table 11 in a parallel relationship with the mounting table 11. In other words, the upper electrode 30 is disposed to face the wafer W mounted on the mounting table 11. The upper electrode 30 is formed of, for example, a conductive metal such as nickel (Ni).

The upper electrode 30 has a plurality of gas supply holes 30a formed to pass through the upper electrode 30 in a thickness direction. In addition, an upwardly-protruded portion 30b is formed in the entire outer peripheral portion of the upper electrode 30. That is to say, the upper electrode 30 has a substantially cylindrical shape with a bottom and an opened upper portion. The upper electrode 30 is smaller in an inner diameter than the processing container 10 such that an outer surface of the protrusion portion 30b is spaced apart from the inner surface of the processing container 10 by a predetermined distance. Further, the upper electrode 30 has a larger diameter than that of the wafer W such that a surface facing the mounting table 11 in the upper electrode 30 covers the entire surface of the wafer W mounted on the mounting table 11 when viewed from the top for example. A cover 31 of a substantially disc shape is connected to an upper end surface of the protrusion portion 30b so that a space enclosed by the cover 31 and the upper electrode 30 is formed as a gas diffusion room 32. Like the upper electrode 30, the cover 31 is formed of a conductive metal such as nickel or the like. In addition, the cover 31 and the upper electrode 30 may be integrally configured.

A locking member 31a is formed in an outer peripheral portion of an upper surface of the cover 31 to protrude outward of the cover 31. A lower surface of the locking member 31a is held by a circular ring-shaped support member 33 which is supported on an upper end portion of the processing container 10. The support member 33 is formed of, for example, an insulating material such as quartz. Thus, the upper electrode 30 and the processing container 10 are electrically insulated from each other. In addition, an electric heater 34 is installed on an upper surface of the cover 31. The cover 31 and the upper electrode 30 connected to the cover 31 can be heated to a predetermined temperature by the electric heater 34.

A gas supply pipe 50 passing through the cover 31 is connected to the gas diffusion room 32. The gas supply pipe 50 is connected to a process gas supply source 51 as shown in FIG. 1. A process gas supplied from the process gas supply source 51 is supplied into the gas diffusion room 32 through the gas supply pipe 50. The process gas supplied into the gas diffusion room 32 is introduced into the processing container 10 through the gas supply holes 30a. In this case, the upper electrode 30 plays a role of a shower plate for introducing the process gas into the processing container 10.

The process gas supply source 51 of the present embodiment includes a raw material gas supply part 52 that supplies a TiCl₄ gas as a raw material gas for forming a Ti film, a reduction gas supply part 53 that supplies, for example, an H₂ (hydrogen) gas as a reduction gas, and a nobble gas supply part 54 that supplies a nobble gas for generating plasma. For example, an argon (Ar) gas is used as the nobble gas supplied from the nobble gas supply part 54. In addition, the process gas supply source 51 includes valves 55 and flow rate regulating mechanisms 56, which are installed between the respective gas supply parts 52, 53 and 54 and the gas diffusion room 32. A flow rate of each gas supplied to the gas diffusion room 32 is controlled by the respective flow rate regulating mechanism 56.

The cover 31 is electrically coupled to a high-frequency power source 60 through a matching device 61. The high-frequency power source 60 supplies a high-frequency power to the upper electrode 30 through the cover 31 so as to generate plasma. The high-frequency power source 60 is configured to output the high-frequency power with a frequency of, for example, 100 kHz to 100 MHz. The matching device 61, which is to match an inner impedance of the high-frequency power source 60 with a load impedance, operates to perpetually match the inner impedance of the high-frequency power source 60 with the load impedance, when the plasma has been generated inside the processing container 10.

An exhaust mechanism 70 configured to exhaust the interior of the processing container 10 is coupled to a bottom surface of the processing container 10 through an exhaust pipe 71. An adjustment valve 72 is installed in the exhaust pipe 71 to adjust an amount of gas to be exhausted by the exhaust mechanism 70. Therefore, it is possible to exhaust an internal atmosphere of the processing container 10 through the exhaust pipe 71 by driving the exhaust mechanism 70, thus depressurizing an internal pressure of the processing container 10 to a predetermined degree of vacuum.

The plasma processing apparatus 1 described above includes a control part 100. The control part 100 is, for example, a computer, and includes a program storage part (not shown). The program storage part stores a program for controlling respective components such as the electric heaters 20 and 34, the flow rate regulating mechanisms 56, the high-frequency power source 60, the matching device 61, the exhaust mechanism 70, the adjustment valve 72 and the like to operate the substrate processing apparatus 1.

In addition, the program is recorded in a computer-readable recording medium such as a computer-readable hard disk (HD), a flexible disk (FD), a compact disc (CD), a magneto-optical disk (MO), a memory card or the like. The program may be installed in the control part 100 from the recording medium.

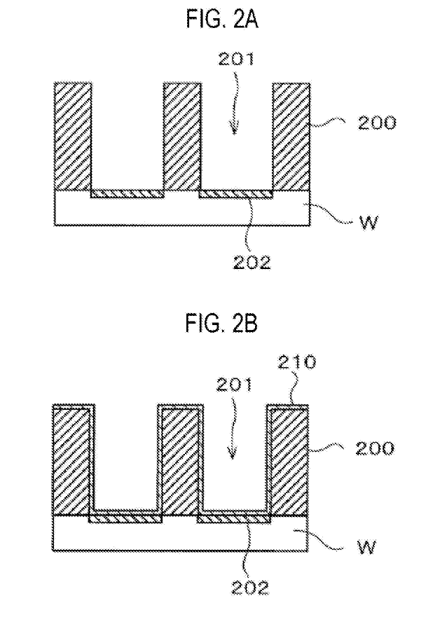

The plasma processing apparatus 1 according to the present embodiment is configured as described above. Next, a film forming process of forming a Ti film on the wafer W in the plasma processing apparatus 1 according to the present embodiment will be described. FIGS. 2A and 2B are views schematically explaining the film forming process of forming the Ti film on the wafer W.

In the film forming process, first, the wafer W is loaded into the processing container 10 and subsequently mounted and held on the mounting table 11. As shown in FIG. 2A, for example, an insulating layer 200 having a predetermined thickness is formed on the surface of the wafer W. Contact holes 201 are formed above respective conductive layers 202 formed on the wafer W, which correspond to source or drain.

Once the wafer W is held on the mounting table 11, the interior of the processing container 10 is exhausted by the exhaust mechanism 70 so that the interior is air-tightly kept. Simultaneously, the TiCl₄ gas, the H₂ gas, and the Ar gas are respectively supplied from the process gas supply source 51 into the processing container 10 at a predetermined flow rate. At this time, the respective flow rate regulating mechanisms 56 are controlled such that the flow rate of the TiCl₄ gas is set to fall within a range of about 5 to 50 sccm, the flow rate of the H₂ gas is set to fall within a range of about 5 to 10,000 sccm, and the flow rate of the Ar gas is set to fall within a range of about 100 to 5,000 sccm. In the present embodiment, the TiCl₄ gas, the H₂ gas, and the Ar gas are supplied at the flow rates of 6.7 sccm, 4,000 sccm and 1,600 sccm, respectively. In addition, an opening degree of the adjustment valve 72 is controlled such that the internal pressure of the processing container 10 is set to fall within a range of, for example, 65 Pa to 1,330 Pa. In the present embodiment, the opening degree of the adjustment valve 72 is approximately 666 Pa.

Simultaneously, the upper electrode 30 and the wafer W mounted on the mounting table 11 are heated to, for example, 400 degrees C. or more, by the respective electric heaters 20 and 34 and a state thus heated is maintained. Continuously, a high-frequency power is applied to the upper electrode 30 by the high-frequency power source 60. Thus, the respective gases supplied into the processing container 10 are plasmarized between the upper electrode 30 and the mounting table 11 used as the lower electrode, thereby generating plasma according to ions or radicals of TiClₓ, Ti, Cl, H, and Ar.

In the surface of the wafer W, TiClₓ as a raw material gas that is decomposed by the plasma is reduced by H radicals or H₃⁺ ions as a reduction gas. Thus, as shown in FIG. 2B, a Ti film 210 is formed on the wafer W. Upon completing the process of the wafer W, the wafer W is unloaded from the processing container 10. Thereafter, a new wafer W is loaded into the processing container 10 and the above series of processes for the wafer W is repeated.

As described above, in the film forming process (for example, the film forming process of forming the Ti film) using a plasma enhanced ALD process (PEALD process) in the plasma processing apparatus 1 according to the present embodiment, a predetermined electric power having a predetermined frequency is supplied from the high-frequency power source 60 to generate plasma inside the processing container 10.

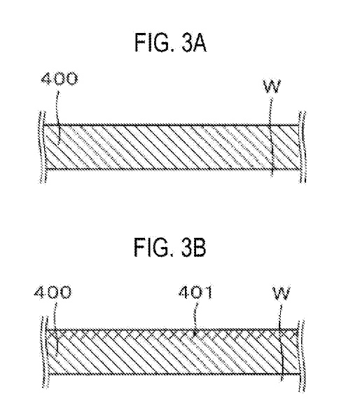

The present inventors have studied the film forming process using the PEALD process through a simulation analysis. As a result, the present inventors found the following facts. For example, a lot of H₂ is supplied into a processing container in which a Ti film is formed by the PEALD process using TiCl₄, H₂, Ar and the like as process gases so that the film forming process is carried out in an H₂-rich atmosphere. As such, the H₃⁺ ions are implanted into a deposited film, thereby causing damage in surface texture. Such damage in surface texture, which does not occur in the CVD-based film forming process, results in deterioration in film quality. FIGS. 3A and 3B are views schematically showing such damage. FIG. 3A is a view schematically showing a portion of a film formed by the CVD process and FIG. 3B is a view schematically showing a portion of a film 400 formed by the PEALD process.

The present inventors have further studied a reason why a damaged portion 401 as shown in FIG. 3A is generated. As a result, the present inventors found the fact that the H₃⁺ ions are incident on the film with high energy. For example, if a high-frequency oscillation is made using a power source with a low frequency of 450 kHz and an application voltage Vₚₚ (a peak-to-peak voltage) of 1,350V, a sheath potential Vs (a potential difference between the plasma and the wafer) is big. This allows the H₃⁺ ions to be implanted deeply into the deposited film.

Upon reference to the foregoing, in the plasma processing apparatus 1 shown in FIG. 1, in the case of adsorbing TiClx as a precursor, which uses TiCl₄ as a raw material, onto a surface of a wafer W, and desorbing Cl from TiClx adsorbed onto the surface of the wafer W to form a Ti film, the present inventors have further studied a technology for suppressing damage caused by the incident ions, which may occur in the Ti film thus formed. As a result, the present inventors found the following findings.

In the case of forming the Ti film, to desorb Cl from the precursor TiClx requires generating H radicals at a predetermined amount or more inside the processing container 10. To meet such a requirement, in the related art, a high-frequency oscillation is carried out using a power source with an application voltage Vₚₚ of 1,350V and a frequency of 450 kHz. In this regard, it was found that it is possible to suppress damage to a deposited film by reducing the energy of the H₃⁺ ions to decrease the sheath potential Vs. In order to reduce the ion energy, the frequency of the power source is required to be higher for the high-frequency oscillation.

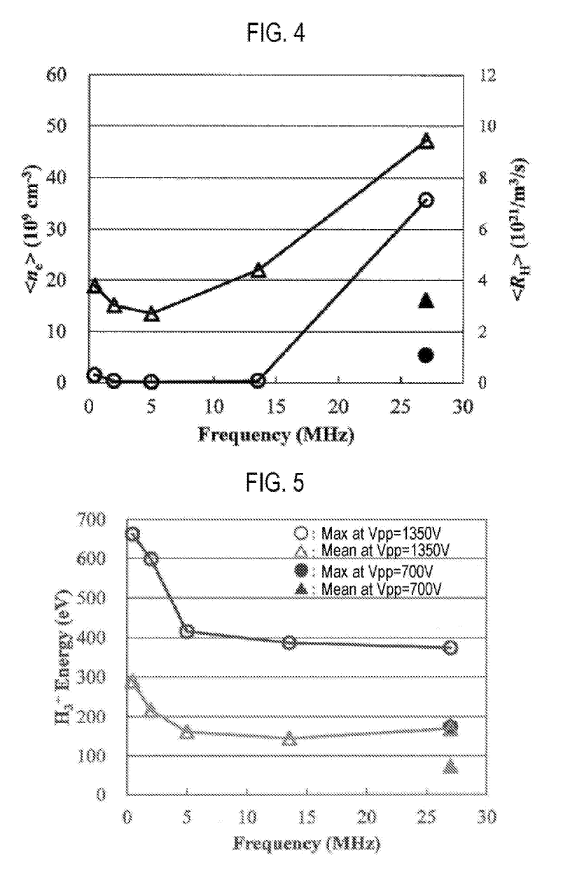

Accordingly, the present inventors calculated a generation rate of H radicals and an energy of H₃⁺ ions by changing a frequency of the power source for the high-frequency oscillation in the case of forming the Ti film in the plasma processing apparatus 1. FIG. 4 is a graph showing a change in electron density (indicated by symbol ◯ in FIG. 4) and a change in generation rate (indicated by symbol Δ in FIG. 4) of the H radicals within the processing container, as a function of a change in frequency of the power source. In addition, in FIG. 4, an electron density (indicated by symbol in FIG. 4) and a generation rate (indicated by symbol ▴ in FIG. 4) of the H radicals within the processing container when changing the application voltage Vₚₚ from 1,350V to 700V at a frequency of 27 MHz, are additionally shown. FIG. 5 is a graph showing a change (a maximum value is indicated by symbol ◯, and a mean value is indicated by symbol Δ, in FIG. 5) in energy of H₃⁺ ions within the processing container, as a function of a change in frequency of the power source.

As shown in FIG. 4, as the frequency of the power source increases, the electron density and the generation rate of the H radicals tend to temporally decrease at the same application voltage Vₚₚ. However, if the frequency exceeds 13.56 MHz, the electron density and the generation rate of the H radicals begins to increase, and are drastically increased as the frequency further increases. Therefore, in the case where the frequency exceeds 13.56 MHz, it is possible to reduce the application voltage Vₚₚ while maintaining the same electron density and the generation rate as the case of applying a frequency of 450 kHz in the related art. For example, in the case in which the frequency of the power source is 27 MHz, it is possible to reduce the application voltage Vₚₚ to 700V while maintaining the electron density and the generation rate of the H radicals at a level substantially equal to those in the case where a high-frequency oscillation is performed using a power source with a frequency of 450 kHz and Vₚₚ of 1,350V.

In addition, as shown in FIG. 5, under the same application voltage Vₚₚ, both the mean and maximum values of energy of the H₃⁺ ions are decreased within the processing container as the frequency of the power source increases. That is to say, it is obvious that the energy of the incident ions decreases with an increase in the frequency of the power source. As described above, since the application voltage Vₚₚ can be reduced at the frequency of 27 MHz, it is also possible to reduce both the mean and maximum values of the incident energy of the ions.

As described above, by increasing the frequency of the power source to a high level and reducing the application voltage Vₚₚ, it is possible to set the electron density and the generation rate of the H radicals at a sufficient level and to reduce the sheath potential Vₛ of the plasma formed on the wafer W, thus lowering the energy of the H₃⁺ ions. This suppresses damage to the deposited film. Here, various sheath potential reducing means for reducing the sheath potential Vₛ of the plasma may be employed. Hereinafter, such a sheath potential reducing means will be described. In addition, in FIG. 1, a sheath potential reducing means 300 is schematically illustrated. The sheath potential reducing means 300 may include a variety of configurations (a DC power source or a waveform tailoring mechanism) to be described below. If necessary, the sheath potential reducing means 300 may be installed inside the high-frequency power source 60.

In the plasma processing apparatus 1, a DC (direct current) power source configured to duplicately apply a DC of a predetermined voltage to the high-frequency power source 60 may be considered as the sheath potential reducing means 300. In particular, the DC power source may apply a DC of a negative voltage to the high-frequency power source 60 (the upper electrode 30) so as to reduce the sheath potential.

More specifically, for example, it may be considered that a DC of −300V as the negative voltage is applied to a high-frequency oscillation power source with a frequency of 27 MHz and an application voltage Vₚₚ of 700V, thereby reducing the sheath potential Vs of the plasma. In this case, the maximum value of the sheath potential Vs of the plasma formed on the wafer W becomes approximately 200V.

In this way, it is possible to suppress the damage to the deposited film by reducing the ion energy. More specifically, it is possible to prevent the H₃⁺ ions with a high energy from being implanted deeply inward of the deposited film, thus preventing the occurrence of the damage.

In addition, according to the review conducted by the present inventors, it was found that the sheath potential can be reduced by tailoring a high-frequency waveform of the high-frequency power source 60 to make a proper waveform. That is to say, it is possible to reduce the sheath potential by installing a waveform tailoring mechanism as the sheath potential reducing means 300.

At this time, a high-frequency waveform of the power for performing the high-frequency oscillation may be tailored in a shape (hereinafter, referred to as Heart Beat waveform) that is configured with a portion corresponding to one wavelength having positive-negative potentials and a portion in which an application voltage is not changed in a length of the same one cycle of a fundamental wavelength, without changing the length of one cycle of the fundamental wavelength.

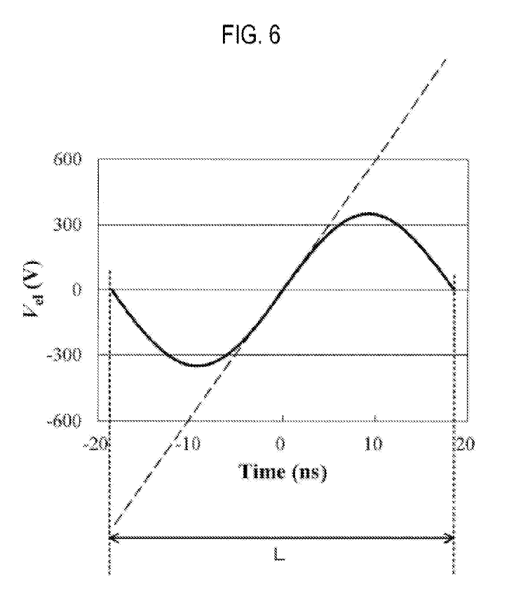

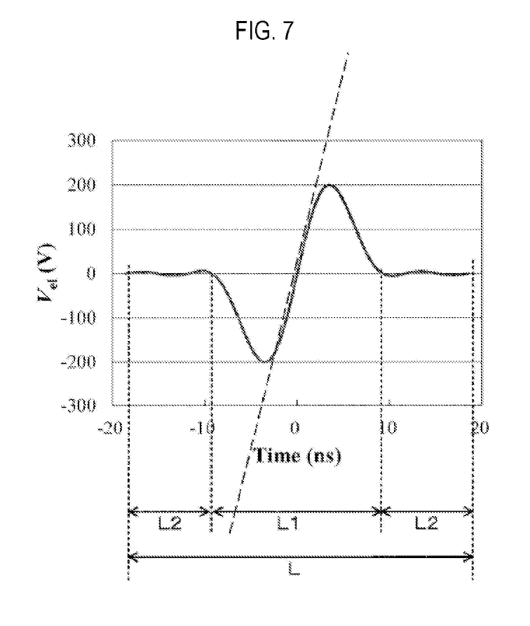

FIGS. 6 and 7 are explanatory views of a high-frequency waveform of the high-frequency power source 60 in the plasma processing apparatus 1 according to the present embodiment. FIG. 6 is a fundamental waveform having a length (one cycle length L) which corresponds to a wavelength of one cycle of a sine wave in a high-frequency power source with a frequency of 27 MHz and an application voltage Vₚₚ of 700V, according to the related art. The fundamental waveform has a slope (shown by a dotted line) as shown in the following Formula (1).

dV/dt=5.94×10¹⁰(V/s) (1)

Meanwhile, FIG. 7 is a high-frequency waveform of a high-frequency power source with a frequency of 27 MHz and an application voltage Vₚₚ of 400V, which may be used in the present embodiment. The wavelength of the waveform shown in FIG. 7 is the same as that of the conventional fundamental waveform (see FIG. 6). The one cycle length L of the waveform is configured with a portion L1 corresponding to one wavelength having positive-negative potentials and portions L2 in which the application voltage is not changed, thereby forming the so-called Heart Beat waveform. In addition, in the portions L2 in which the application voltage is not changed, the application voltage may be changed at such an extent so as not to be substantially involved in the generation of plasma. In the high-frequency waveform according to the present embodiment, the slope of the portion L1 corresponding to one wavelength of positive-negative potentials may be formed to have any shape as long as it is greater than the slope shown in Formula (1). For example, the slope of the portion L1 may have a value represented by the following Formula (2).

dV/dt=9.18×10¹⁰(V/s) (2)

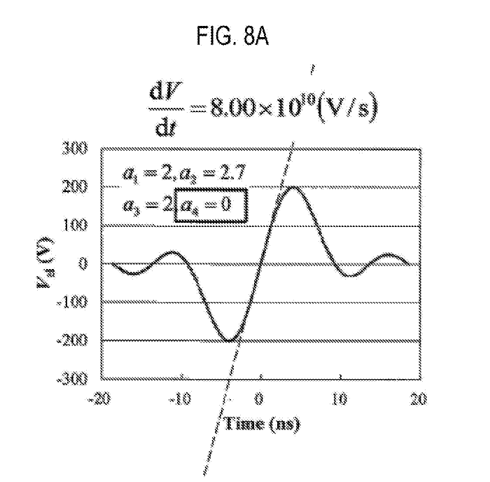

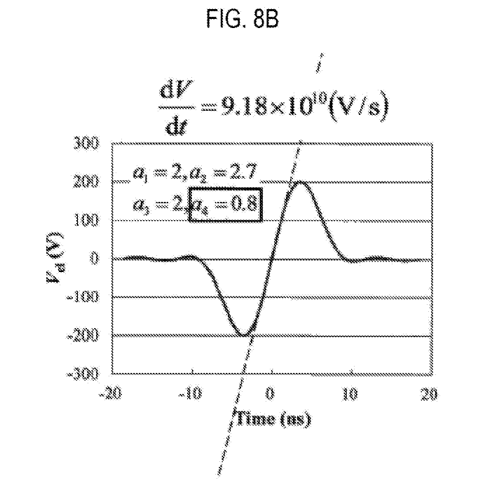

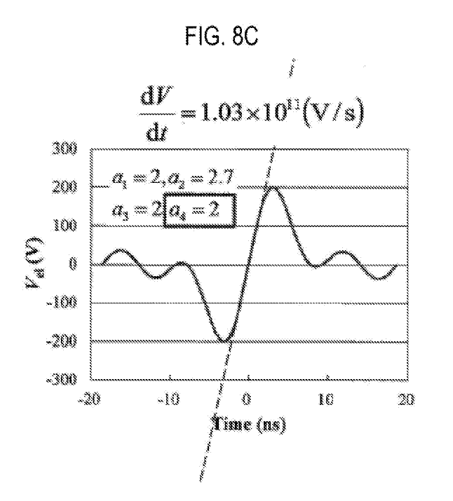

FIGS. 8A to 8C show waveforms obtained when changing the slope of the portion L1 corresponding to one wavelength having positive-negative potentials in a high-frequency waveform according to the present embodiment. The slopes of the waveforms are shown to be increased in the order of FIGS. 8A to 8C. FIG. 8A shows the slope of dV/dt=8.00×10¹⁰(V/s), FIG. 8B shows the slope of dV/dt=9.18×10¹⁰(V/s), and FIG. 8C shows the slope of dV/dt=1.03×10¹¹(V/s).

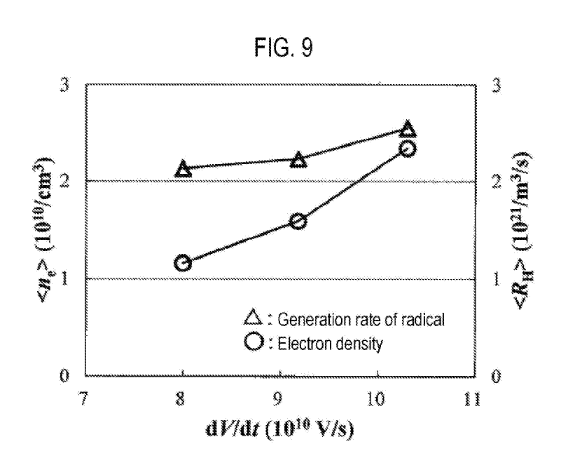

In addition, FIG. 9 is a graph showing a change in the electron density (plasma density) and a change in the generation rate of the H radicals when the slope (dV/dt) increases as illustrated in FIGS. 8A to 8C in the high-frequency waveform according to the present embodiment.

As shown in FIGS. 8A to 8C and FIG. 9, in the plasma processing apparatus 1 according to the present embodiment, in the case of adopting a high-frequency power source which generates the so-called Heart Beat waveform as the high-frequency power source 60, the electron density and the generation rate of the H radical increase as the slope of the portion L1 corresponding to one wavelength having positive-negative potentials increases. From this, it can be seen that the waveform is tailored such that the slope of the portion L1 corresponding to one wavelength having positive-negative potentials in the high-frequency waveform according to the present embodiment becomes big.

In other words, in the high-frequency waveform according to the present embodiment, it is possible to reduce the ion energy while maintaining the electron density and the generation rate of the H radicals as the slope of the portion L1 corresponding to one wavelength having positive-negative potentials increases. By performing a plasma process using the high-frequency waveform tailored as described above according to the present embodiment, it is possible to reduce the application voltage Vₚₚ and reduce the sheath potential Vs of the plasma formed on the wafer W, thereby lowering the energy of the H₃⁺ ions. This suppresses damage to the deposited film.

In addition, the amplitude of the high-frequency waveform according to the present embodiment may be optionally tailored. From the viewpoint of reducing the sheath potential Vs of the plasma, the amplitude of the high-frequency waveform may be set as small as possible.

For example, in a case where a potential waveform, which is tailored by superimposing a sine wave used as a fundamental wave until a harmonic wave corresponding to n-times of the sine wave is obtained, is applied to an electrode, a potential V(t) of the electrode is represented by the following Formula (3).

$$V ( t ) = {V}_{0} {\sum }_{n = 1}^{4} {a}_{n} sin ( n ω t ) \qquad ( 3 )$$

The electrode potential represented by Formula (3) has a maximum slope dV/dt as represented by the following Formula (4) for t=m/f (where, m is an integer and f is a frequency).

$$\frac{dV ( mT )}{dt} = ω {V}_{0} {\sum }_{n = 1}^{4} {a}_{n} n \qquad ( 4 )$$

The maximum value represented by the above Formula (4) is proportional to the frequency f=ω/(2π) and the amplitude V₀ of the fundamental wave. In addition, aₙ denotes a coefficient in relation to the tailoring of waveform.

In order to not increase the potential of plasma, V₀ is required to be set as small as possible. However, in order to facilitate the generation of plasma, the value of Vₚₚ (proportional to V₀) that appears as superimposed waveforms is required to be greater than an ionization threshold energy (εᵢₒₙ) of a process gas. That is to say, it is necessary to satisfy the following Formula (5).

Vₚₚ>εᵢₒₙ (5)

Meanwhile, a value of f is required to be larger in order to reduce Vₒ as much as possible. However, since electrons need to move in response to an electric field, an electron plasma frequency f_{p,e} becomes the upper limit. As described above, since the high-frequency waveform is superposed up to the harmonic wave corresponding to n-times of the fundamental wave, the upper limit of the frequency of the fundamental wave is determined by the following Formula (6).

$$nf < {f}_{p , c} = \frac{e}{2 π} \sqrt{\frac{{n}_{e}}{{ɛ}_{0} {m}_{c}}} \qquad ( 6 )$$

Where, e denotes an elementary charge, ε₀ denotes a dielectric constant in vacuum, nₑ denotes an electron density in plasma, and mₑ denotes an electron's mass.

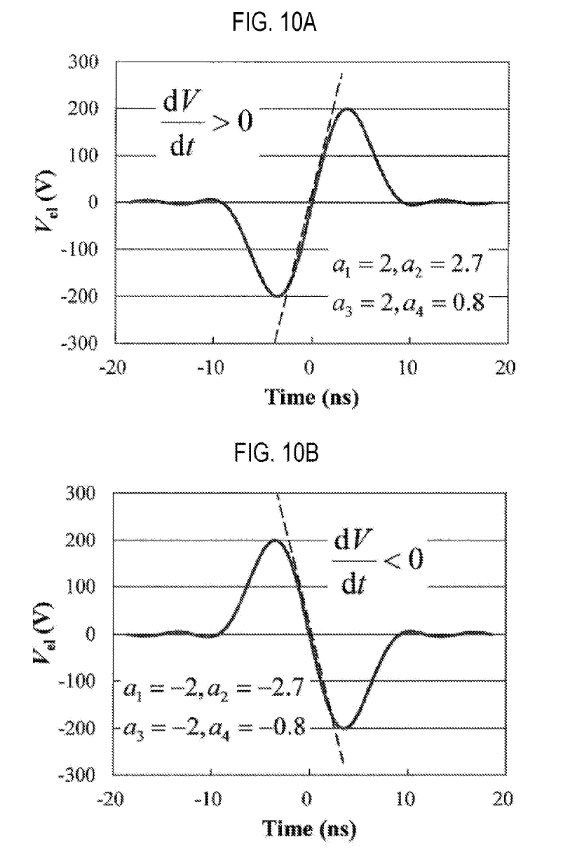

Further, in the high-frequency waveform according to the present embodiment, it is necessary to study dependency on sign of the slope of the portion L1 corresponding to one wavelength having positive-negative potentials. FIGS. 10A and 10B are views for explaining dependency on sign of the high-frequency waveform according to the present embodiment, wherein the absolute values of all the slopes are 9.18×10¹⁰(V/s). FIG. 10A shows the case of dV/dt>0, and FIG. 10B shows the case of dV/dt<0.

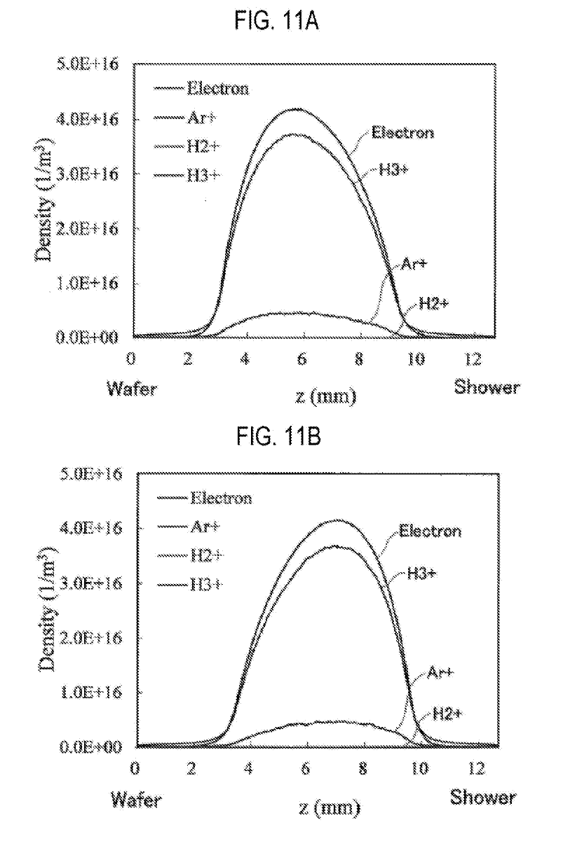

In addition, FIGS. 11A and 11B are explanatory views illustrating an electron density distribution between the wafer (ground electrode) and the shower (drive electrode) corresponding to the respective high-frequency waveforms shown in FIGS. 10A and 10B.

As shown in FIGS. 10A and 10B, and FIGS. 11A and 11B, in the high-frequency waveforms according to the present embodiment, even when the positive or negative sign of the slope of the portion L1 corresponding to one wavelength having positive-negative potentials is changed, the fundamental electron density distribution inside the process container does not change much. However, the electron density distribution is further biased to the wafer W in the case of dV/dt>0 (FIG. 10A), compared to the case of dV/dt<0 (FIG. 10B). That is to say, the sheath at the side of the wafer W for dV/dt<0 is thicker than that for dV/dt>0 so that the frequency of collision between the ions and the gas molecules in the sheath is increased. Thus, it is possible to further reduce the energy of the ions incident onto the wafer W.

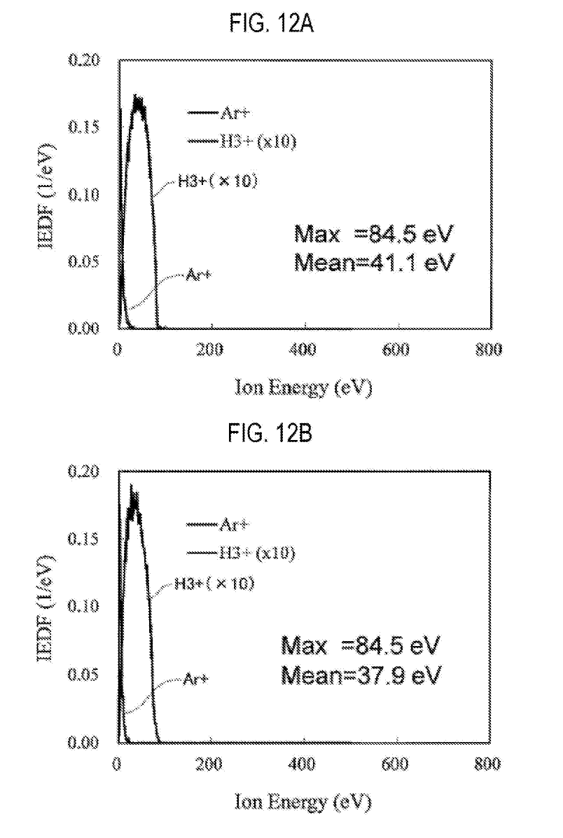

FIGS. 12A and 12B are graphs showing a change in the ion energy in the case of performing the high-frequency oscillation using high-frequency power sources of the respective high-frequency waveforms shown in FIGS. 10A and 10B, and FIGS. 11A and 11B when forming a Ti film in the plasma processing apparatus 1 according to the present embodiment. As shown in FIGS. 12A and 12B, comparing the case of dV/dt>0 in FIGS. 12A with the case of dV/dt<0 in FIGS. 12B, the maximum values of the incident ion energy are the same, whereas the mean value is suppressed at a relatively low level in the case of dV/dt<0 rather than the case of dV/dt>0.

That is to say, in the plasma processing apparatus 1 according to the present embodiment, the high-frequency oscillation may be performed using the high-frequency power source capable of tailoring the so-called Heart Beat waveform. Furthermore, by tailoring the high-frequency waveform such that the sign of the slope of the portion L1 corresponding to one wavelength having positive-negative potentials is dV/dt<0, it is possible to predict a further reduction in the ion energy. It is therefore possible to further suppress the damage to the deposited film.

In addition, when tailoring a waveform into the high-frequency waveform according to the present embodiment, a high-frequency power having a period during which the so-called Heart Beat waveform shown in FIG. 7 is repeated without interruption may be used as the power which performs the high-frequency oscillation. Alternatively, a high-frequency power having a period during which the so-called Heart Beat waveform has a predetermined empty interval periodically, may be used as the power which performs the high-frequency oscillation. However, in either case, the waveform is required to be tailored to have a period during which plasma is sufficiently generated inside the processing container 10 and such a state is continuously maintained.

As described above, the film forming process performed by the plasma processing apparatus 1 according to the present embodiment, may adopt a method which uses the DC (direct current) power source which duplicately applies a DC of a predetermined voltage to the high-frequency power source 60 for performing the high-frequency oscillation as the sheath potential reducing means 300, or may adopt a method which uses a waveform tailoring mechanism that tailors a high-frequency waveform of a power source to generate the so-called Heart Beat waveform as the sheath potential reducing means 300. According to the aforementioned methods, it is possible to reduce the sheath potential Vs of plasma and lower the ion energy, thus suppressing the damage to the deposited film, which occurs in the conventional film forming process.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

For example, the above embodiment has been described with an example where a means configured to apply the DC of a predetermined voltage to the power source for performing the high-frequency oscillation (the case where the DC power source is installed) or a means configured to tailor the waveform of the power source for performing the high-frequency oscillation (the case where the waveform tailoring mechanism is installed), is used as the sheath potential reducing means 300. One or both of these means may be installed in the plasma processing apparatus 1.

In addition, in the above embodiment, a means for generating plasma in the processing container 10 has been described but not limited thereto. As a plasma source for generating plasma in the processing container, an inductively coupled plasma (ICP) which applies a high-frequency through an antenna formed in a coil shape and generates plasma by an inductive coupling through a dielectric window. Alternatively, other plasma sources such as a helicon wave plasma or a cyclotron resonance plasma may be used as the plasma source for generating plasma in the processing container.

In addition, for example, although the plasma enhanced ALD process has been described as an example in the above embodiment, the present disclosure may be applied to, for example, an ALE (Atomic Layer Etching) process or the like.

The present disclosure may be applied to a substrate processing apparatus which performs a film forming process on a surface of a substrate.

According to the present disclosure in some embodiments, it is possible to, in a substrate processing apparatus which performs a PEALD process, significantly reduce energy of ions to be incident onto a wafer and to suppress damage to a deposited film, which is caused by implantation of the ions, thus implementing a film forming process with good surface texture.

What is claimed is:

1. A substrate processing apparatus which performs a film forming process by supplying a raw material gas to a substrate and irradiating plasma onto the substrate, the apparatus comprising:
a processing container configured to hermetically accommodate a mounting table on which the substrate is mounted; and
a plasma source configured to generate plasma in the processing container,
wherein the plasma source includes:
a high-frequency power source that generates plasma; and
a sheath potential reducing means configured to reduce a sheath potential of the generated plasma.

2. The apparatus of claim 1, wherein the sheath potential reducing means is a direct current power source installed to duplicately apply a voltage to the high-frequency power source.

3. The apparatus of claim 2, wherein the voltage applied to the high-frequency power source from the direct current power source is a negative voltage.

4. The apparatus of claim 1, wherein the sheath potential reducing means includes a waveform tailoring mechanism configured to tailor a high-frequency waveform in the plasma source, and
the waveform tailoring mechanism tailors the high-frequency waveform of the plasma source to have a shape configured by a portion corresponding to one wavelength having positive-negative potentials and a portion in which an application voltage is not changed, in a length of one cycle of waveform.

5. The apparatus of claim 4, wherein, in the high-frequency waveform tailored by the waveform tailoring mechanism, the portion corresponding to one wavelength having positive-negative potentials has a negative slope.

6. The apparatus of claim 4, wherein, in the high-frequency waveform tailored by the waveform tailoring mechanism, a frequency of the portion corresponding to one wavelength having positive-negative potentials exceeds 13.56 MHz.

7. The apparatus of claim 1, wherein the sheath potential reducing means includes:
a direct current power source configured to duplicately apply a voltage to the high-frequency power source; and
a waveform tailoring mechanism configured to tailor a high-frequency waveform in the plasma source.
